(19) United States
(12) Patent Application Publication
(10) Pub. No.: US 2025/0117155 A1
(43) Pub. Date: Apr. 10, 2025

(54) MEMORY DEVICE FOR PERFORMING UNDER-DRIVE OPERATION AND METHOD OF OPERATING THE SAME

(71) Applicant: SK hynix Inc., Icheon-si Gyeonggi-do (KR)

(72) Inventor: Eun Woo JO, Icheon-si Gyeonggi-do (KR)

(73) Assignee: SK hynix Inc., Icheon-si Gyeonggi-do (KR)

(21) Appl. No.: 18/586,939

(22) Filed: Feb. 26, 2024

(30) Foreign Application Priority Data
Oct. 5, 2023 (KR) 10-2023-0132722

(51) Int. Cl. G06F 3/06

(52) U.S. Cl. CPC G06F 3/0655; G06F 3/0604; G06F 3/0673

(57) ABSTRACT

Provided herein are a memory device and a method of operating the memory device. The memory device may include a memory cell array including a plurality of memory cells coupled to a selected word line, a voltage generator configured to generate an operating voltage that is used for an internal operation, a row decoder configured to perform an under-drive operation including decreasing a voltage level of the selected word line and to apply the operating voltage to the selected word line, and control logic configured to control the row decoder to apply a ground voltage to the selected word line during the under-drive operation.

### CROSS-REFERENCE TO RELATED APPLICATION

The present application claims priority under 35 U.S.C. § 119 (a) to Korean patent application number 10-2023-0132722 filed on Oct. 5, 2023, in the Korean Intellectual Property Office, the entire disclosure of which is incorporated herein by reference.

### BACKGROUND

### 1. Technical Field

Various embodiments of the present disclosure generally relate to a semiconductor device, and more particularly to a memory device for performing an under-drive operation and a method of operating the memory device.

### 2. Related Art

Memory devices may be devices in which data is stored and may be classified as either a volatile memory device or a nonvolatile memory device.

Such a memory device may perform a read operation of reading data stored in a memory cell. During the read operation, the memory device may perform an under-drive operation and thereafter apply a read voltage to a word line coupled to the memory cell. In this example, the under-drive operation is an operation including decreasing the voltage level of the word line and is intended to improve the setting of the word line.

### SUMMARY

An embodiment of the present disclosure provides for a memory device. The memory device may include a memory cell array including a plurality of memory cells coupled to a selected word line, a voltage generator configured to generate an operating voltage that is used for an internal operation, a row decoder configured to perform an under-drive operation including decreasing a voltage level of the selected word line and to apply the operating voltage to the selected word line, and control logic configured to control the row decoder to apply a ground voltage to the selected word line during the under-drive operation.

An embodiment of the present disclosure provides for a memory device. The memory device may include a memory cell array including a plurality of memory cells coupled to a selected word line; a voltage generator configured to generate a plurality of operating voltages for distinguishing a plurality of states corresponding to the plurality of memory cells, wherein the plurality of states comprises first states and second states; a row decoder configured to perform an under-drive operation including decreasing a voltage level of the selected word line and to apply the plurality of operating voltages to the selected word line; and control logic configured to control the row decoder to apply a ground voltage to the selected word line during the under-drive operation corresponding to first states and to apply an under-drive voltage to the selected word line during the under-drive operation corresponding to second states.

An embodiment of the present disclosure provides for a method of operating a memory device. The method may include applying a first operating voltage to a selected word line coupled to a plurality of memory cells, sensing the plurality of memory cells based on the first operating voltage, applying a ground voltage to the selected word line, generating a second operating voltage, applying the second operating voltage to the selected word line, and sensing the plurality of memory cells based on the second operating voltage.

An embodiment of the present disclosure provides for a method of operating a memory device. The method may include applying a first operating voltage to a selected word line coupled to a plurality of memory cells; generating a plurality of operating voltages for distinguishing a plurality of states corresponding to the plurality of memory cells, wherein the plurality of states comprises first states and second states; applying a ground voltage to the selected word line during a first under-drive operation corresponding to the first states; and applying an under-drive voltage to the selected word line during a second under-drive operation corresponding to the second states.

The second states may have a threshold voltage lower than a threshold voltage corresponding to the first states.

### BRIEF DESCRIPTION OF THE DRAWINGS

FIG. 1 is a diagram illustrating a memory device according to an embodiment of the present disclosure.

FIG. 2 is a diagram illustrating voltages applied to a selected word line according to an embodiment of the present disclosure.

FIG. 3 is a diagram illustrating an example of an under-drive operation according to an embodiment of the present disclosure.

FIG. 4 is a diagram illustrating an example of an under-drive operation according to another embodiment of the present disclosure.

FIG. 5 is a flowchart illustrating a method of operating a memory device according to an embodiment of the present disclosure.

### DETAILED DESCRIPTION

Specific structural or functional descriptions in the embodiments of the present disclosure introduced in this specification or application are provided as examples to describe embodiments according to the concept of the present disclosure. The embodiments according to the concept of the present disclosure may be practiced in various forms and should not be construed as being limited to the embodiments described in the specification or application.

Various embodiments of the present disclosure are directed to a memory device and a method of operating the memory device, which can reduce the time required for a read operation and a verify operation. During an under-drive operation, decreasing the voltage of the word line to a sufficiently low level and reducing the time to perform the under-drive operation may be advantageously performed.

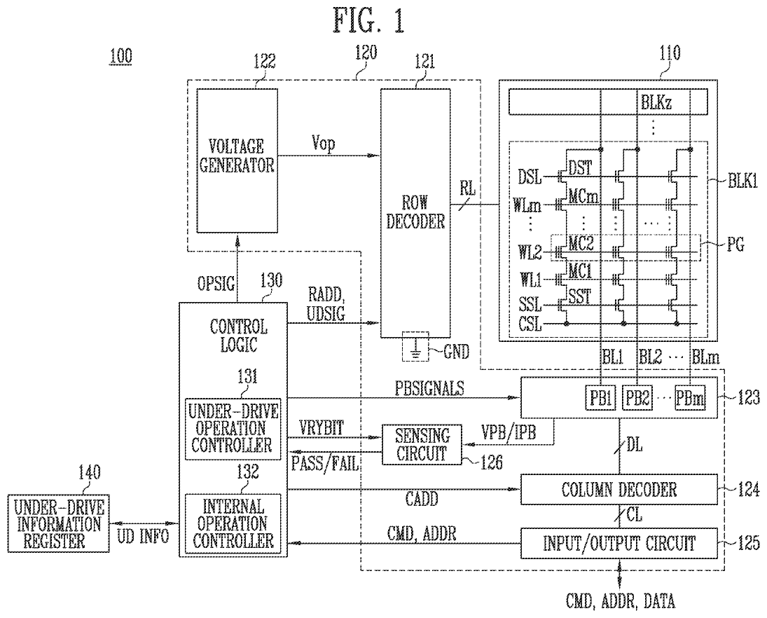

FIG. 1 is a diagram illustrating a memory device according to an embodiment of the present disclosure.

Referring to FIG. 1, a memory device 100 may include a memory cell array 110, a peripheral circuit 120, and control logic 130.

The memory cell array 110 may include a plurality of memory blocks BLK1 to BLKz.

The plurality of memory blocks BLK1 to BLKz is coupled to a row decoder 121 through row lines RL. For example, the row lines RL may include at least one source select line SSL, a plurality of word lines WL1 to WLm, and at least one drain select line DSL. The source select lines SSL are coupled to source select transistors SST. The source select transistors SST may be coupled between a common source line CSL and a plurality of memory cells MC1 to MCm. The drain select lines DSL are coupled to drain select transistors DST. The drain select transistors DST may be coupled between a plurality of bit lines BL1 to BLm and the plurality of memory cells MC1 to MCm.

Each of the memory blocks BLK1 to BLKz may include the plurality of memory cells MC1 to MCm. The plurality of memory cells MC1 to MCm may be coupled to a page buffer circuit 123 through the plurality of bit lines BL1 to BLm. Memory cells coupled to the same word line may be considered as one page PG. Each of the memory cells MC1 to MCm may store a plurality of data bits.

Each of the memory cells may correspond to any one of a plurality of states. For example, the plurality of states may include an erase state and a plurality of program states distinguished based on threshold voltages. Each of the memory cells may be a memory cell in an erase state or a memory cell programmed to any one of the plurality of program states.

The peripheral circuit 120 may perform a program operation, a read operation, or an erase operation on a selected area of the memory cell array 110 under the control of the control logic 130.

The peripheral circuit 120 may include the row decoder 121, a voltage generator 122, the page buffer group 123, a column decoder 124, an input/output circuit 125, and a sensing circuit 126.

The row decoder 121 may decode a row address RADD received from the control logic 130. The row decoder 121 selects at least one of the memory blocks BLK1 to BLKz depending on the decoded address. Further, the row decoder 121 may select, depending on the decoded address, at least one word line of the memory block. The row decoder 121 applies voltages Vop generated by the voltage generator 122 to the selected word line.

For example, during a program operation, the row decoder 121 may apply a program voltage to the selected word line and apply a program pass voltage having a lower voltage than the program voltage to unselected word lines. During a program verify operation, the row decoder 121 may apply a verify voltage to the selected word line and apply a verify pass voltage higher than the verify voltage to unselected word lines. During a read operation, the row decoder 121 may apply a read voltage to the selected word line and apply a read pass voltage higher than the read voltage to unselected word lines.

In an embodiment, the row decoder 121 may perform an under-drive operation including decreasing the voltage level of the selected word line during a read operation or a verify operation. For example, the row decoder 121 may apply an under-drive voltage or a ground voltage to the selected word line in response to an under-drive control signal UDSIG received from the control logic. The under-drive voltage may be provided from the voltage generator 122. The row decoder 121 may be directly coupled or connected to ground GND and may apply a corresponding ground voltage Vgnd to the memory cell array 110. The ground voltage Vgnd may be supplied from ground GND.

The voltage generator 122 generates an internal supply voltage by regulating an external supply voltage that is supplied to the memory device 100. The internal supply voltage generated by the voltage generator 122 may be used as an operating voltage for the memory device 100. The voltage generator 122 may generate various operating voltages Vop that are used for program, read, and erase operations in response to an operation signal OPSIG. For example, the voltage generator 122 may generate a program voltage, a verify voltage, a pass voltages, a read voltage, an under-drive voltage, and so forth. The generated voltages Vop may be supplied to the memory cell array 110 by the row decoder 121.

The page buffer group 123 includes a plurality of page buffers PB1 to PBm. The plurality of page buffers PB1 to PBm may temporarily store data received through the plurality of bit lines BL1 to BLm or sense the voltages or currents of the plurality of bit lines BL1 to BLm during a read or verify operation in response to page buffer control signals PBSIGNALS.

The column decoder 124 may transfer data between the input/output circuit 125 and the page buffer group 123 in response to a column address CADD.

The input/output circuit 125 may transmit a command CMD and an address ADDR, received from a memory controller, to the control logic 130 or may exchange data DATA with the column decoder 124.

The sensing circuit 126 may determine whether a verify operation for a specific program state has passed by applying the verify voltage.

In an example, during the verify operation, the sensing circuit 126 may generate a reference current in response to an enable bit signal VRYBIT and may compare a sensing voltage VPB received from the page buffer group 123 with a reference voltage generated by the reference current and in response output a pass signal PASS or a fail signal FAIL. In an example, during a verify operation, the sensing circuit 126 may generate a reference voltage in response to the enable bit signal VRYBIT and may compare a sensing current IPB received from the page buffer group 123 with a reference current generated by the reference voltage and in response output a pass signal PASS or a fail signal FAIL.

The control logic 130 may control the peripheral circuit 120 by outputting the operation signal OPSIG, the row address RADD, the under-drive control signal UDSIG, and the page buffer control signals PBSIGNALS in response to the command CMD and the address ADDR.

In an embodiment, the control logic 130 may include an under-drive operation controller 131 and an internal operation controller 132.

The under-drive operation controller 131 may control an under-drive operation. For example, the under-drive operation controller 131 may control the peripheral circuit 120 such that the voltage level of a selected word line is decreased before the read voltage or the verify voltage is applied to the selected word line.

In an embodiment, the under-drive operation controller 131 may control the under-drive operation based on an under-drive operation performance scheme UD INFO determined depending on the plurality of states. For example, the under-drive operation controller 131 may receive the under-drive operation performance scheme UD INFO corresponding to each of the plurality of states from an under-drive information register 140. The under-drive information register 140 may store the under-drive operation performance scheme UD INFO for each state of the plurality of states.

In an embodiment, the under-drive operation controller 131 may control the row decoder 121 to apply the ground voltage to the selected word line during an under-drive operation corresponding to first states among the plurality of states.

In an embodiment, the under-drive operation controller 131 may control the voltage generator 122 to generate the under-drive voltage during an under-drive operation corresponding to second states among the plurality of states. The under-drive operation controller 131 may control the row decoder 121 to apply the under-drive voltage to the selected word line during the under-drive operation corresponding to the second states. In this example, the second states may be states having a threshold voltage lower than the threshold voltage corresponding to the first states.

The internal operation controller 132 controls the peripheral circuit to perform an internal operation such as a read operation, a program operation, or a verify operation. For example, the internal operation controller 132 may control the voltage generator 122 to generate an operating voltage Vop used for the internal operation and may control the row decoder 121 to apply the operating voltage Vop to the selected word line after the under-drive operation.

In an embodiment, the control logic 130 controls the row decoder 121 to sequentially apply the plurality of operating voltages Vop to the selected word line in descending order of voltage levels, i.e., from a highest voltage level to a lowest voltage level. The plurality of operating voltages Vop may be voltages that distinguish the plurality of states from each other.

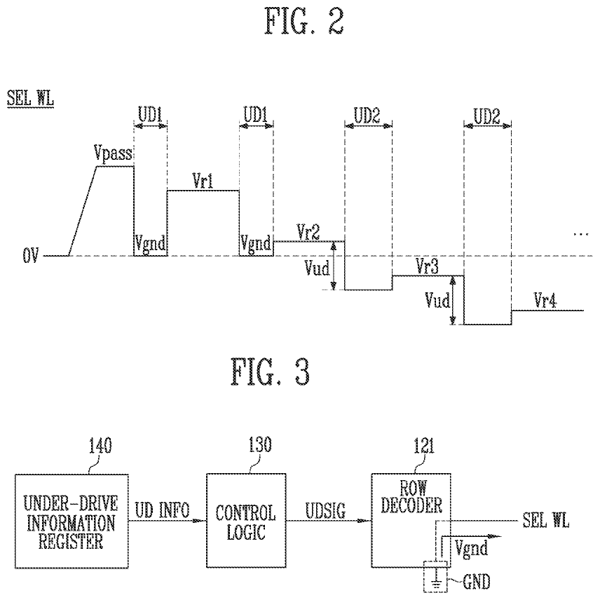

FIG. 2 is a diagram illustrating voltages applied to a selected word line according to an embodiment of the present disclosure. In FIG. 2, for convenience of description, the voltages applied to the selected word line during a read operation will be described. Description made with reference to FIG. 2 may also be applied to voltages that are applied to a selected word line during a verify operation or any other operation.

Referring to FIG. 2, the memory device 100 may apply a pass voltage Vpass to a selected word line SEL WL. In this example, the pass voltage Vpass may be applied to turn on or precharge the selected word line.

In an embodiment, the memory device 100 may perform an under-drive operation on the selected word line SEL WL, and thereafter apply read voltages Vr1, Vr2, Vr3, and Vr4 to the selected word line SEL WL. The read voltages Vr1, Vr2, Vr3, and Vr4 may be sequentially applied in descending order of voltage levels.

In an embodiment, the memory device 100 may perform an under-drive operation depending on a first under-drive performance scheme UD1 before applying the first read voltage Vr1 and the second read voltage Vr2 for distinguishing first states of memory cells from each other. In this example, the first under-drive performance scheme UD1 may be an under-drive operation using a ground voltage Vgnd.

For example, the memory device 100 may apply the pass voltage Vpass to the selected word line SEL WL and thereafter apply the ground voltage Vgnd to the selected word line SEL WL. Accordingly, through the under-drive operation, the voltage level of the selected word line SEL WL may be a voltage level corresponding to the ground voltage Vgnd. Thereafter, the memory device 100 may apply the first read voltage Vr1 to the selected word line SEL WL. After the read operation is performed based on the first read voltage Vr1, the memory device 100 may apply the ground voltage Vgnd to the selected word line SEL WL. Accordingly, the voltage level of the selected word line SEL WL may again be a voltage level corresponding to the ground voltage Vgnd.

In an embodiment, the memory device 100 may perform an under-drive operation depending on a second under-drive performance scheme UD2 before applying the third read voltage Vr3 and the fourth read voltage Vr4 for distinguishing second states of memory cells from each other. In this example, the second under-drive performance scheme UD2 may be an under-drive operation using an under-drive voltage Vud.

For example, after the read operation is performed based on the second read voltage Vr2, the memory device 100 may apply the under-drive voltage Vud to the selected word line SEL WL. Accordingly, the voltage level of the selected word line SEL WL may be a voltage level decreased from the current voltage Vr2 by the under-drive voltage Vud through the under-drive operation. Thereafter, the memory device 100 may apply the third read voltage Vr3 to the selected word line SEL WL. After the read operation is performed based on the third read voltage Vr3, the memory device 100 may apply the under-drive voltage Vud to the selected word line SEL WL. Accordingly, the voltage level of the selected word line SEL WL may be a voltage level decreased from the current voltage Vr3 by the under-drive voltage Vud.

The first states may include states in which the voltage level of the selected word line SEL WL is a positive voltage level even though the under-drive operation is performed. That is, when the voltage level of the selected word line SEL WL is higher than the under-drive voltage Vud before an under-drive operation for a specific state among the plurality of states is performed, the specific state may correspond to the first states. In this case, the read voltages Vr1 and Vr2 corresponding to the first states may have positive voltage levels.

Furthermore, the second states may include states in which the voltage level of the selected word line SEL WL is a negative voltage level when the under-drive operation is performed. For example, when the voltage level of the selected word line SEL WL is lower than the value of the under-drive voltage Vud before an under-drive operation for a specific state among the plurality of states is performed, the specific state may correspond to one of the second states. In this example, the read voltages Vr1 and Vr2 corresponding to the second states may have positive voltage levels or negative voltage levels.

For example, when each memory cell is implemented as a quad-level cell (QLC) capable of storing four data bits, each memory cell may correspond to any one of an erase state and first to fifteenth program states. The first program state may correspond to the lowest threshold voltage, and the fifteenth program state may correspond to the highest threshold voltage. In this example, the twelfth to fifteenth program states may correspond to the first states, and the erase state and the first to eleventh program states may correspond to the second states. Although each memory cell is a quad-level cell in the above-described example, the present disclosure is not limited such an example, and the memory cell may be a multi-level cell (MLC) that stores two data bits or a triple-level cell (TLC) that stores three data bits.

FIG. 3 is a diagram illustrating an example of an under-drive operation according to an embodiment of the present disclosure. The under-drive operation illustrated in FIG. 3 may be an under-drive operation corresponding to the first under-drive performance scheme UD1, described above with reference to FIG. 2.

Referring to FIG. 3, the control logic 130 may receive under-drive operation performance scheme UD INFO from the under-drive information register 140.

In an embodiment, the under-drive operation performance scheme UD INFO may be information indicating whether the under-drive operation to be performed depends on a first under-drive performance scheme UD1 or depends on a second under-drive performance scheme UD2 for each state.

For example, when the under-drive operation corresponding to first states is performed, the control logic 130 may control the under-drive operation depending on the first under-drive performance scheme UD1 based on the under-drive operation performance scheme UD INFO.

The control logic 130 may generate an under-drive control signal UDSIG that instructs the under-drive operation to be performed depending on the determined scheme and may provide the under-drive control signal UDSIG to the row decoder 121.

In an embodiment, the row decoder 121 may couple the selected word line SEL WL to ground GND in response to the under-drive control signal UDSIG. Accordingly, the voltage level of the selected word line SEL WL may be decreased to a voltage level corresponding to a ground voltage Vgnd provided from ground GND.

In an embodiment, the control logic 130 may adjust the strength of the under-drive operation by controlling the time during which the ground voltage Vgnd is applied to the selected word line SEL WL. In an example, the control logic 130 may raise the strength of the under-drive operation by increasing the time during which the ground voltage Vgnd is applied to the selected word line SEL WL. Accordingly, the voltage level of the selected word line SEL WL may be decreased to a voltage value as close as possible to the voltage level corresponding to the ground voltage Vgnd. In an example, the control logic 130 may lower the strength of the under-drive operation by decreasing the time during which the ground voltage Vgnd is applied to the selected word line SEL WL. Accordingly, the voltage level of the selected word line SEL WL may be decreased to a voltage value further from the voltage level corresponding to the ground voltage Vgnd.

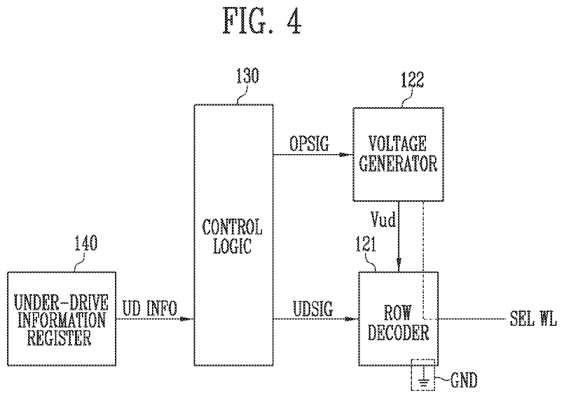

FIG. 4 is a diagram illustrating an example of an under-drive operation according to another embodiment of the present disclosure. The under-drive operation illustrated in FIG. 4 may be an under-drive operation corresponding to the second under-drive performance scheme UD2, described above with reference to FIG. 2.

Referring to FIG. 4, the control logic 130 may receive an under-drive operation performance scheme UD INFO from the under-drive information register 140.

For example, when the under-drive operation corresponding to second states is performed, the control logic 130 may control the under-drive operation depending on the second under-drive performance scheme UD2 based on the under-drive operation performance scheme UD INFO.

In an embodiment, the control logic 130 provides an operation signal OPSIG to the voltage generator that instructs an under-drive voltage Vud to be generated. The voltage generator 122 generates the under-drive voltage Vud in response to the operation signal OPSIG. The voltage generator 122 provides the generated under-drive voltage Vud to the row decoder 121, for example, directly or indirectly.

The control logic 130 may generate an under-drive control signal UDSIG that instructs the under-drive operation to be performed depending on the determined scheme and may provide the under-drive control signal UDSIG to the row decoder 121.

In an embodiment, the row decoder 121 applies the under-drive voltage Vud to the selected word line SEL WL in response to the under-drive control signal UDSIG. In this example, the selected word line SEL WL may be coupled to the voltage generator 122. Accordingly, the voltage level of the selected word line SEL WL may be a voltage level decreased by the under-drive voltage Vud from a voltage level before the under-drive operation is performed. In this example, the voltage level of the selected word line SEL WL may be decreased to have a negative voltage level.

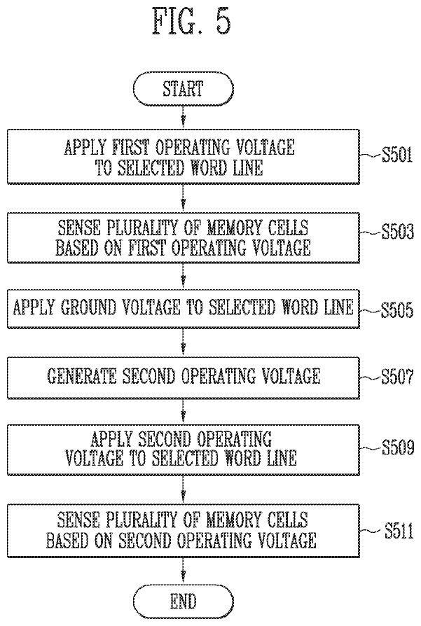

FIG. 5 is a flowchart illustrating a method of operating a memory device according to an embodiment of the present disclosure.

The method illustrated in FIG. 5 may be performed by, for example, the memory device 100 illustrated in FIG. 1.

Referring to FIG. 5, the memory device 100 applies S501 a first operating voltage to a selected word line coupled to a plurality of memory cells. The memory device 100 may, for example, apply the first operating voltage, higher than a ground voltage and higher than a second operating voltage, to the selected word line. Further, the memory device 100 may apply the first operating voltage having a positive voltage level to the selected word line.

The memory device 100 senses S503 a plurality of memory cells based on the first operating voltage.

The memory device 100 applies S505 the ground voltage to the selected word line. For example, the memory device 100 may apply the ground voltage such that the voltage level of the selected word line is decreased from the first operating voltage to the ground voltage.

The memory device 100 generates S507 the second operating voltage.

The memory device 100 applies S509 the second operating voltage to the selected word line. For example, the memory device 100 may apply the second operating voltage having a positive voltage level to the selected word line.

The memory device 100 senses S511 the plurality of memory cells based on the second operating voltage.

According to the present disclosure, a memory device and a method of operating the memory device are provided, which may reduce the time required for a read operation and a verify operation.

What is claimed is:

1. A memory device comprising:
a memory cell array including a plurality of memory cells coupled to a selected word line;
a voltage generator configured to generate an operating voltage that is used for an internal operation;
a row decoder configured to perform an under-drive operation including decreasing a voltage level of the selected word line and to apply the operating voltage to the selected word line; and
control logic configured to control the row decoder to apply a ground voltage to the selected word line during the under-drive operation.

2. The memory device according to claim 1, wherein:
the internal operation includes at least one of a read operation and a verify operation, and
the operating voltage includes at least one of a read voltage and a verify voltage.

3. The memory device according to claim 1, wherein the row decoder is coupled to ground and is configured to provide the ground voltage.

4. The memory device according to claim 3, wherein the row decoder couples the selected word line to the ground voltage during the under-drive operation.

5. The memory device according to claim 1, wherein the control logic is configured to adjust strength of the under-drive operation by controlling a time during which the ground voltage is applied to the selected word line.

6. The memory device according to claim 1, wherein the operating voltage has a positive voltage level.

7. The memory device according to claim 1, wherein, through the under-drive operation, the voltage level of the selected word line is a voltage level corresponding to the ground voltage.

8. A memory device comprising:
a memory cell array including a plurality of memory cells coupled to a selected word line;
a voltage generator configured to generate a plurality of operating voltages for distinguishing a plurality of states corresponding to the plurality of memory cells, wherein the plurality of states comprises first states and second states;
a row decoder configured to perform an under-drive operation including decreasing a voltage level of the selected word line and to apply the plurality of operating voltages to the selected word line; and
control logic configured to control the row decoder to apply a ground voltage to the selected word line during the under-drive operation corresponding to first states and to apply an under-drive voltage to the selected word line during the under-drive operation corresponding to second states, wherein the second states have a threshold voltage lower than a threshold voltage corresponding to the first states.

9. The memory device according to claim 8, further comprising an under-drive information register configured to store an under-drive operation performance scheme corresponding to each of the plurality of states.

10. The memory device according to claim 8, wherein, through the under-drive operation corresponding to the first states, the control logic is configured to control the row decoder such that the voltage level of the selected word line is a voltage level corresponding to the ground voltage.

11. The memory device according to claim 8, wherein, through the under-drive operation corresponding to the second states, the control logic is configured to control the row decoder such that the voltage level of the selected word line is a negative voltage level.

12. The memory device according to claim 8, wherein the control logic is configured to control the row decoder such that the plurality of operating voltages are sequentially applied to the selected word line in descending order of voltage levels.

13. A method of operating a memory device, the method comprising:
applying a first operating voltage to a selected word line coupled to a plurality of memory cells;
sensing the plurality of memory cells based on the first operating voltage;
applying a ground voltage to the selected word line;
generating a second operating voltage;
applying the second operating voltage to the selected word line; and
sensing the plurality of memory cells based on the second operating voltage.

14. The method according to claim 13, wherein applying the first operating voltage comprises applying the first operating voltage, higher than the ground voltage and the second operating voltage, to the selected word line.

15. The method according to claim 13, wherein applying the first operating voltage comprises applying the first operating voltage having a positive voltage level to the selected word line.

16. The method according to claim 13, wherein applying the second operating voltage comprises applying the second operating voltage having a positive voltage level to the selected word line.

17. The method according to claim 13, wherein applying the ground voltage comprises decreasing the voltage level of the selected word line from the first operating voltage to the ground voltage.
